(19) United States
(12) Patent Application Publication
(10) Pub. No.: US 2024/0395731 A1
(43) Pub. Date: Nov. 28, 2024

(54) ELECTRONIC DEVICE WITH A REINFORCING LAYER

(71) Applicant: TEXAS INSTRUMENTS INCORPORATED, DALLAS, TX (US)

(72) Inventors: Masamitsu Matsuura, Oita (JP); Anindya Poddar, Sunnyvale, CA (US); Daiki Komatsu, Hiji (JP); Hau Thanh Nguyen, San Jose, CA (US); Patrick Francis Thompson, Allen, TX (US)

(21) Appl. No.: 18/321,192

(22) Filed: May 22, 2023

(51) Int. Cl. H01L 23/00; H01L 21/027; H01L 21/56; H01L 23/495

(52) U.S. Cl. CPC H01L 23/562; H01L 21/0274; H01L 21/565; H01L 21/568; H01L 23/49513; H01L 24/16; H01L 24/32; H01L 24/48; H01L 24/73; H01L 2224/16245; H01L 2224/32225; H01L 2224/32245; H01L 2224/48245; H01L 2224/73203; H01L 2224/73215; H01L 2224/73265; H01L 2924/16151; H01L 2924/16195; H01L 2924/16235; H01L 2924/165; H01L 2924/16587; H01L 2924/16588; H01L 2924/182

(57) ABSTRACT

An electronic device includes a leadframe having a die pad and leads. A die that includes an active layer is attached to the die pad. A reinforcement layer is disposed on the active layer and wire bonds are attached from the active layer of the die to the leads. A mold compound encapsulates the die, the reinforcement layer, and the wire bonds.

### TECHNICAL FIELD

The present disclosure relates to an electronic device and more specifically, to an integrated circuit package having a reinforcing cap.

### BACKGROUND

Trenches formed in a die from an active side of the die to the opposite side have several applications, including for use in through silicon vias (TSV's) packages, such as, isolation packages where the trenches are filled with an isolating/barrier material (e.g., polyimide, silicon dioxide (SiO₂)), sensors where the trenches are filled with a conductive material (e.g., copper), etc. Unfortunately, due to a difference in thermal expansion (Coefficient of Thermal Expansion (CTE) mismatch) between the die (e.g., silicon die) and the trench filler material, cracks can form in the metal active layer of the die where the trench meets the metal active layer. Specifically, the CTE mismatch causes stress in the package, which can create the cracks. In addition, additional mechanical stresses caused during the manufacturing process (e.g., handling) can exacerbate the stresses and cause more cracks.

### SUMMARY

In described examples, an electronic device includes a leadframe having a die pad and leads. A die that includes an active layer is attached to the die pad. A reinforcement layer is disposed on the active layer and wire bonds are attached from the active layer of the die to the leads. A mold compound encapsulates the die, the reinforcement layer, and the wire bonds.

In still another described example, a method includes providing a carrier and a die, where the die has an active layer. A first etching process is performed to the carrier and the die and the die is bonded to the carrier to create a die assembly. A mounting side of the die is backgrinded and a second etching process is performed on the die to create at least one trench in the die. At least one of a dielectric material or an electrically conductive material is deposited in the at least one trench and on the mounting side of the die. The carrier is backgrinded and the die assembly is placed on a die pad of a leadframe. Wire bonds from the active layer of the die to leads of the leadframe and a molding compound is formed over the die, the carrier, the wire bonds, and all but one surface of the leadframe, the one surface facing away from the die.

In still another described example, a die assembly includes a die having an active layer and a mounting side opposite that of the active layer. At least one trench is formed in the die, where the at least one trench extends from the mounting side to the active layer. A reinforcement layer is disposed on the active layer, where the reinforcement layer comprised of a wafer carrier to carry the die during fabrication.

### BRIEF DESCRIPTION OF THE DRAWINGS

FIG. 1A illustrates a cross-sectional view of an example electronic device.

FIG. 1B illustrates a close-up view of a section of the electronic device in FIG. 1A.

FIG. 2A illustrates cross-sectional views of a carrier and a die in the early stages of fabrication.

FIG. 2B illustrates cross-sectional views of the carrier and the die of FIG. 2A after undergoing a formation of photoresist material layers.

FIG. 2C illustrates cross-sectional views of the carrier and the die of FIG. 2B after undergoing an etching process.

FIG. 2D illustrates cross-sectional views of the carrier and the die of FIG. 2C after removal of the photoresist material layers.

FIG. 2E illustrates cross-sectional views of the carrier and the die of FIG. 2D after undergoing a deposition of a bonding material on the die.

FIG. 2F illustrates a cross-sectional view of the carrier and the die of FIG. 2E after undergoing a bonding of the carrier and the die.

FIG. 2G illustrates a cross-sectional view of the carrier and the die of FIG. 2F after undergoing a backgrinding process to the die.

FIG. 2H illustrates a cross-sectional view of the carrier and the die of FIG. 2G after undergoing the formation of a photoresist material layer on the die.

FIG. 2I illustrates a cross-sectional view of the carrier and the die of FIG. 2H after undergoing an etching process.

FIG. 2J illustrates a cross-sectional view of the carrier and the die of FIG. 2I after undergoing a deposition process.

FIG. 2K illustrates a cross-sectional view of the carrier and the die of FIG. 2J after a 180° rotation of the carrier and the die.

FIG. 2L illustrates a cross-sectional view of the carrier and the die of FIG. 2K after undergoing a backgrinding process to the carrier.

FIG. 2M illustrates a cross-sectional view of the carrier and the die of FIG. 2L after attachment to a leadframe.

FIG. 2N illustrates cross-sectional views of the carrier and the die of FIG. 2M after attachment of wire bonds.

FIG. 2O illustrates cross-sectional views of the carrier and the die of FIG. 2N after the formation of a molding compound.

FIG. 3 illustrates a cross-sectional view of another example electronic device.

### DETAILED DESCRIPTION

Integrated circuit (IC) packages can include a die or dies having one or more trenches formed from an active metal layer of the die to an opposite side of the die. Such IC packages can be used in various applications, including for use in through silicon vias (TSV's) packages, such as, isolation packages where the trenches are filled with an isolating/barrier material (e.g., polyimide, silicon dioxide (SiO₂)), sensors where the trenches are filled with a conductive material (e.g., copper), etc. The difference, however, in thermal expansion (Coefficient of Thermal Expansion (CTE) mismatch) between the die (e.g., silicon die) and the trench filler material can cause cracks to form in the active metal layer of the die where the one or more trenches meet the active metal layer. Additional mechanical stresses caused during the manufacturing process (e.g., handling) can exacerbate the stresses and cause more or larger cracks.

An alternative solution is to increase a thickness of insulation in the active metal layer of the die in order to minimize cracking. This, however, results in an increase in the amount of time required to fabricate the package. In addition, the increase in the thickness of the insulation increases the thickness of the active layer of the die. As a result, the overall thickness of the package increases, which is undesirable.

Disclosed herein is an electronic device and method of fabricating the electronic device that overcomes the challenges described above. The electronic device includes a die mounted to a leadframe where the die includes at least one trench formed therein. The trench extends from an active layer of the die to an opposite side of the die and is filled with an isolating material or a conductive material. The active layer of the die includes one or more metal layers embedded in an insulating layer. The one or more metal layers provide electrical conduction from the die to the leadframe via wire bonds. A reinforcement layer (cap) is attached to the active side of the die via a bonding material. More specifically, the reinforcement layer is comprised of the original wafer carrier (e.g., silicon carrier, glass carrier, ceramic carrier) that is attached to the die during fabrication of the electronic device. Rather than removing the carrier from the die during fabrication, the carrier is etched to facilitate the connection of wire bonds to the die, and then backgrinded to serve as the reinforcement layer. The reinforcement layer provides stiffness to the active layer of the die to prevent cracks from forming between the trench material and the active layer of the die.

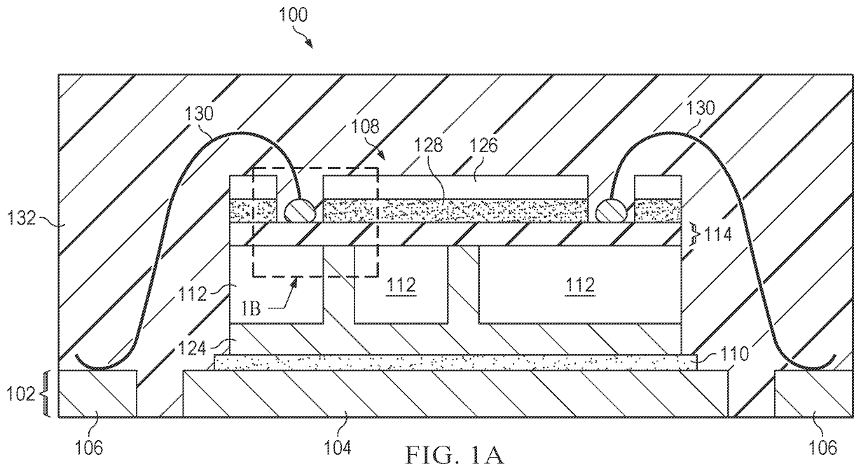

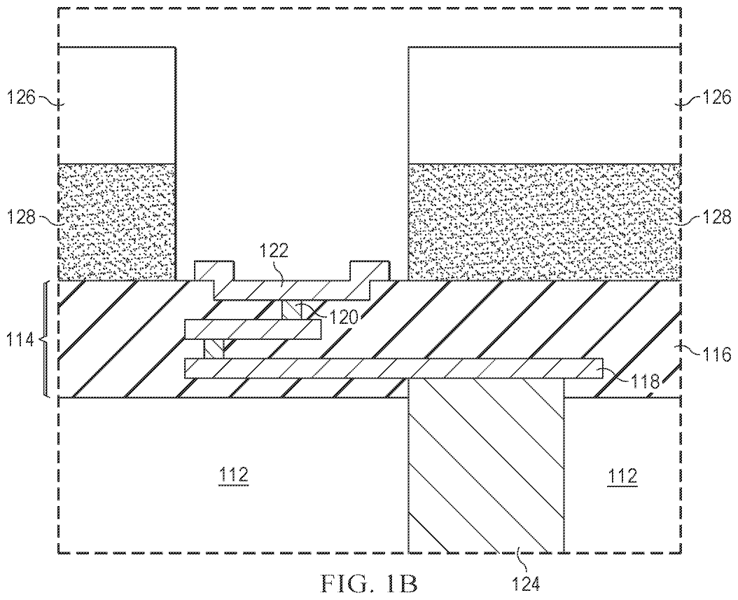

FIG. 1A is a cross-sectional view of an example electronic device (e.g., integrated circuit (IC) package) 100 that includes a reinforcement layer. FIG. 1B is a close-up view of a section of the electronic device 100 in FIG. 1A. The electronic device 100 includes a leadframe 102 comprising a die pad 104 and leads 106. A die assembly 108 is attached to the die pad 104 of the leadframe 102 via a die attach material 110. The electronic device 100 can be comprised of non-leaded or leaded integrated circuit packages. Some example IC packages can include a quad flat no-lead (QFN) package, a quad flat package (QFP), a small outline package (SOP), a single in-line package (SIP), a double in-line package (DIP), etc.

The die assembly 108 includes a die 112 having an active layer 114 disposed on an active side of the die 112. As illustrated in FIG. 1B, the active layer 114 includes an insulation layer 116 that may include one or more layers of SiO2, SiON, or SiN., and one or more metal layers (e.g., copper, aluminum, etc.) 118 embedded in the insulation layer 116. Vias (e.g., tungsten) 120 provide an interconnection between the metal layers 118. Although, there are two metal layers 118 illustrated in FIG. 1B, it is understood that there may be any number of metal layers 118. Thus, the example illustrated in FIG. 1B is for illustrative purposes only and is a non-limiting example. The active layer 114 further includes a wire bond pad (e.g., aluminum, copper) 122 for bonding wire bonds to the die 112. One or more trenches 124 are defined in the die 112 and extend from the active layer 114 of the die 112 to an opposite side of the die 112. The trenches 124 are filled with either an isolating/barrier material (e.g., polyimide, SiO₂) for use in isolation packages or with a conductive material (e.g., copper) for use in sensor packages.

The die assembly 108 further includes a reinforcement layer (cap) 126 attached to the active layer 114 of the die 112 via a bonding material 128. The reinforcement layer 126 provides additional stiffness to the active layer 114 and the die 112 to reduce the potential for cracks as explained above. The reinforcement layer 126 is comprised of the original wafer carrier (e.g., silicon carrier, glass carrier, ceramic carrier) that is attached to the die 112 during fabrication of the electronic device 100 explained further below. Openings are formed in the reinforcement layer 126 where the wire bond pad 122 is disposed to allow the connection of wire bonds 130 to the active layer 114 of the die 112. The wire bonds 130 provide a connection from the active layer 114, via the wire bond pad 122 to the leads 106 of the leadframe 102. A mold compound 132 is formed over and encapsulates the die assembly 108 including, the die 112, the reinforcement layer 126, and the wire bonds 130. In addition, the mold compound 132 covers all but one surface of the leadframe 102, where the one surface not covered faces away from the die and the electronic device 100.

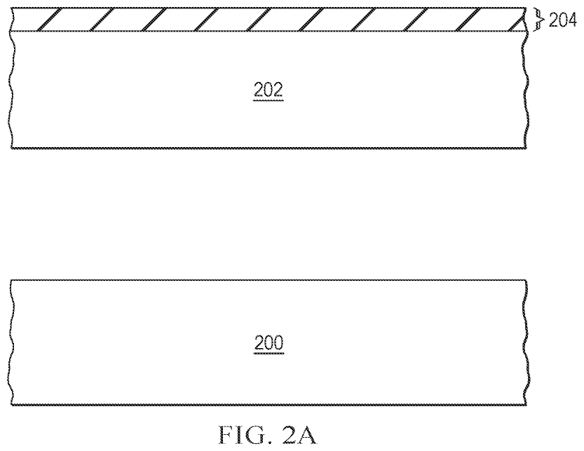

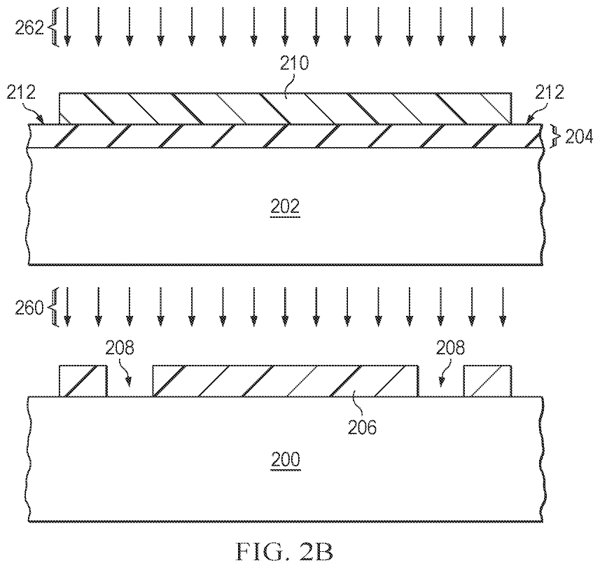

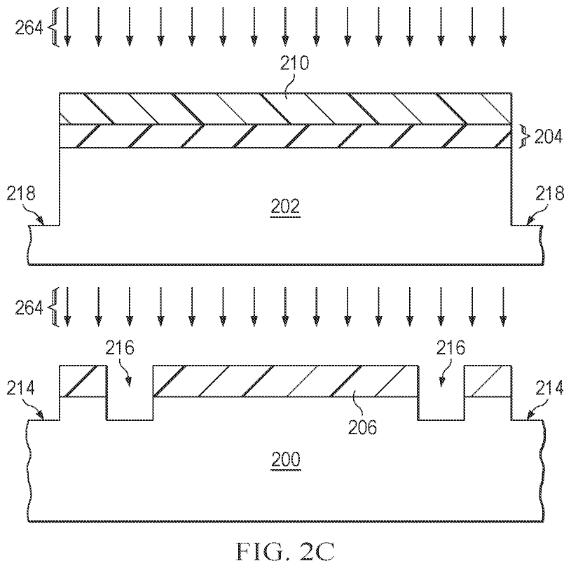

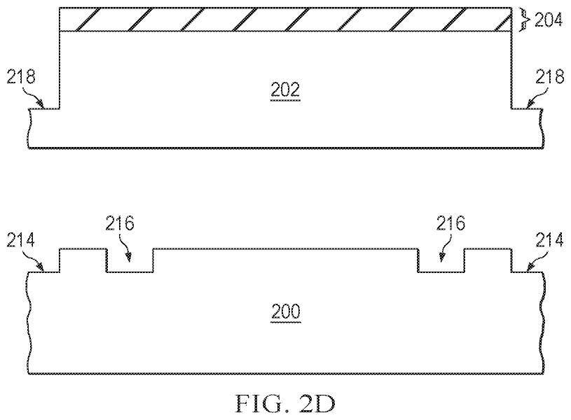

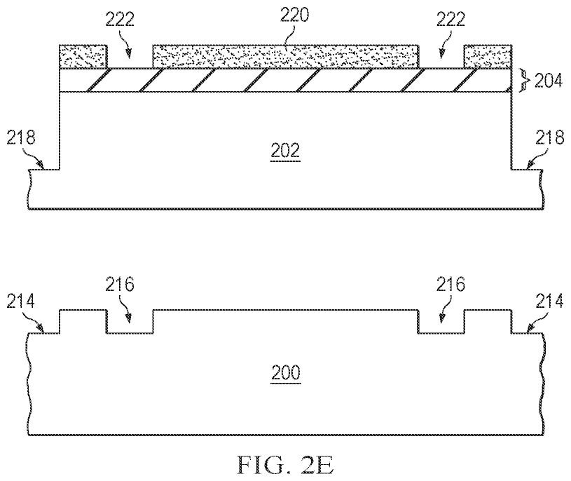

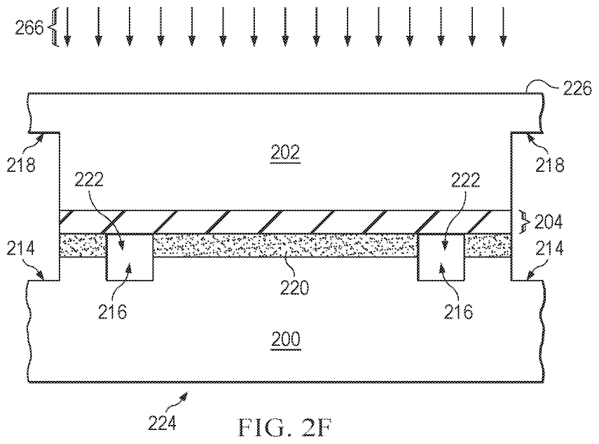

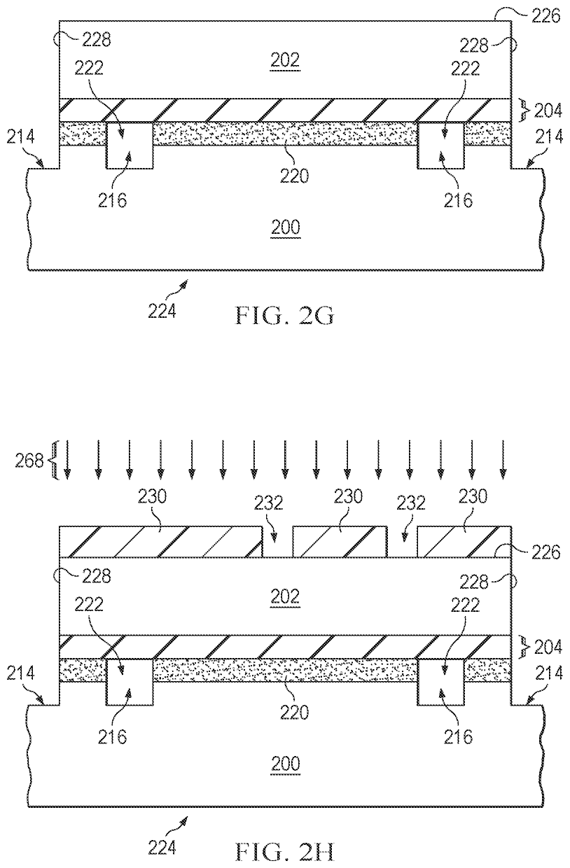

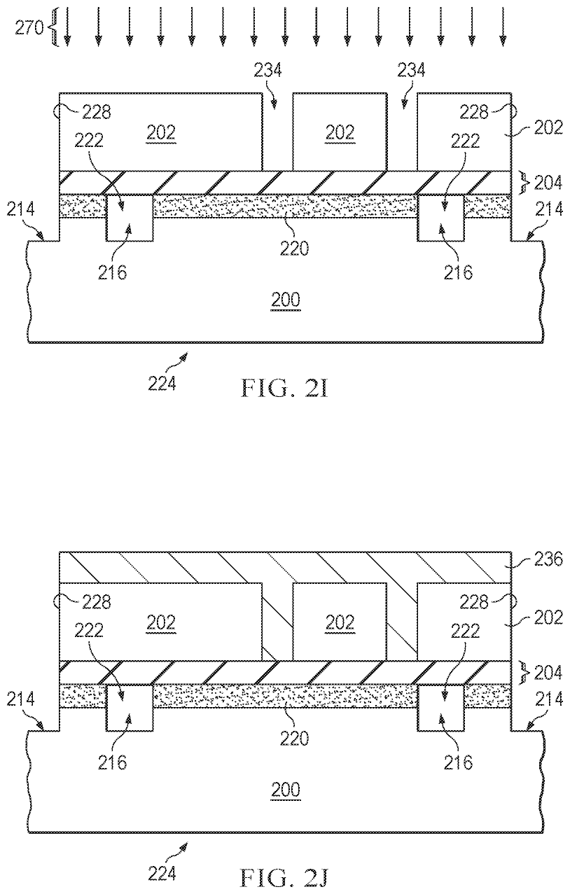

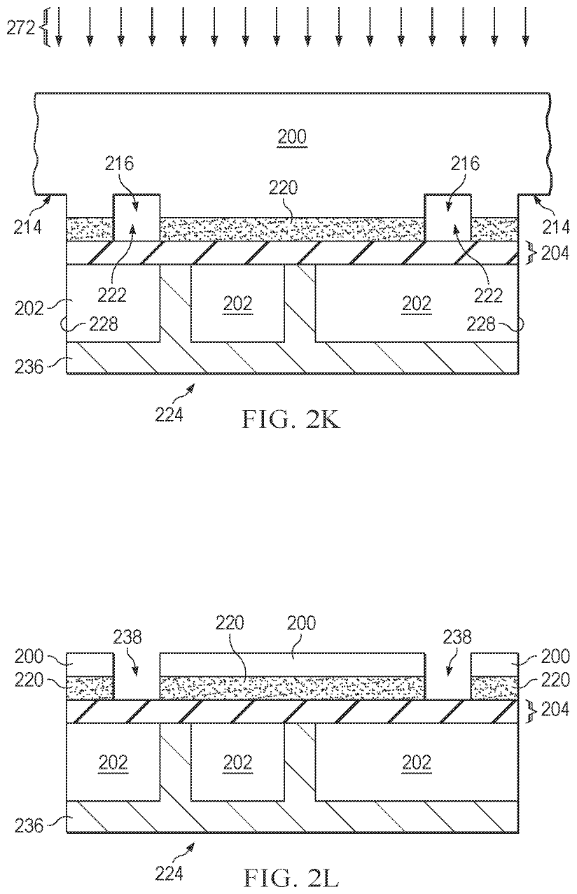

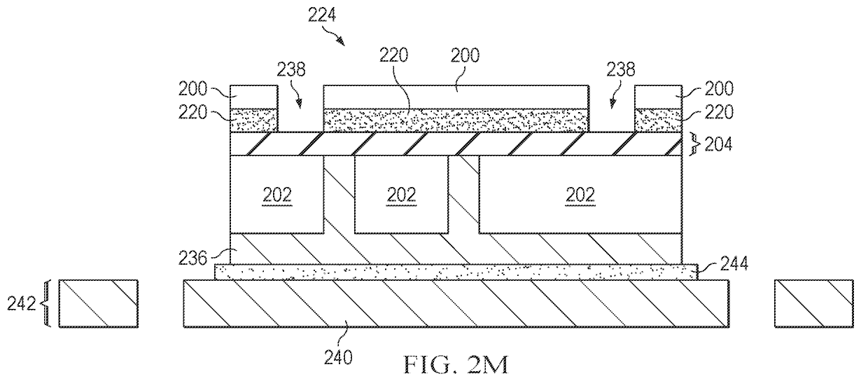

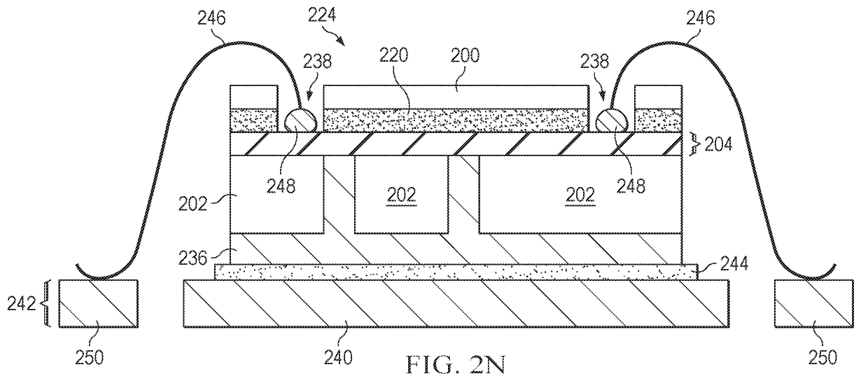

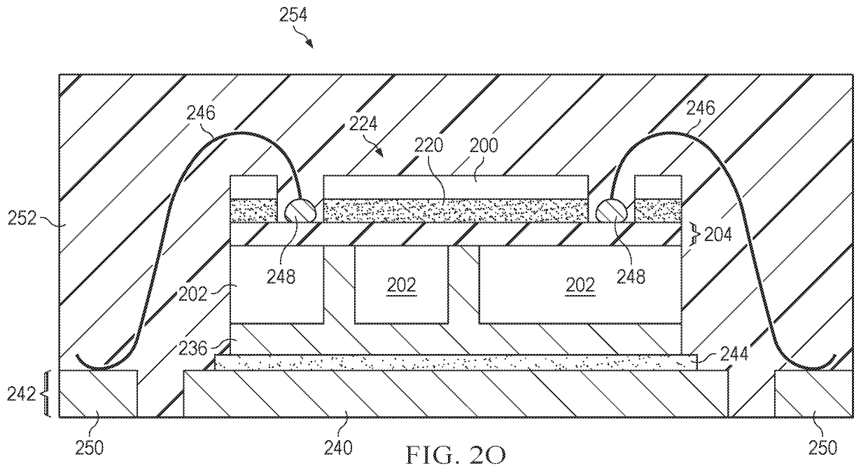

FIGS. 2A-2P illustrate the fabrication process associated with the formation of the electronic device 100 illustrated in FIG. 1A. Though depicted sequentially as a matter of convenience, at least some of the actions shown can be performed in a different order and/or performed in parallel. Alternatively, some implementations may perform only some of the actions shown. Still further, although the example illustrated in FIGS. 2A-2P is an example method illustrating the example configuration of FIG. 1A, other methods and configurations are possible. It is understood that although the method illustrated in FIGS. 2A-2P illustrates the fabrication process of a single electronic device, the process applies to an array of electronic devices. Thus, after fabrication of the array of electronic device the array is singulated to separate each electronic device from the array.

Referring to FIG. 2A, the fabrication process begins with a substrate to carry dies during fabrication. More specifically, the process begins with the substrate comprised of a wafer carrier (e.g., silicon wafer carrier, glass wafer carrier, ceramic wafer carrier, etc.) 200 and a die 202. The die 202 includes an active layer 204 similar to the active layer 114 illustrated in FIG. 1B. Referring to FIG. 2B, a first photoresist material layer 206 overlies the carrier 200 and is patterned and developed to create openings 208 to thereby expose a portion or portions of the carrier 200. Still referring to FIG. 2B, a second photoresist layer 210 overlies the active layer 204 of the die 202 and is patterned and developed to create openings 212 to thereby expose a portion or portions of the active layer 204 and the die 202. The first and second photoresist material layers 206, 210 can have a thickness that varies in correspondence with the wavelength of radiation used to pattern the first and second photoresist material layers 206, 210. The first and second photoresist material layers 206, 210 may be formed via spin-coating, spin casting deposition techniques, laser printing, or film type photoresist lamination selectively irradiated (e.g., via deep ultraviolet (DUV) irradiation).

The configuration in FIG. 2B undergoes a first etching process 260, 262 resulting in the configuration in FIG. 2C. Specifically, the carrier 200 undergoes a first etching process 260 to create a recessed edge 214 on each side of the carrier 200 and to form openings 216 in the carrier 200. In addition, the die 202 undergoes a first etching process 262 to create a recessed edge 218 on each side of the die 202. The first and second photoresist material layers 206, 210 are removed via a photoresist etching process 264 resulting in the configuration of FIG. 2D. A bonding material 220 is deposited on the active layer 204 of the die 202 and is patterned to form openings 222 thereby partially exposing a surface of the active layer 204 resulting in the configuration of FIG. 2E. The die 202 in FIG. 2E is rotated 180° and is bonded to the carrier 200 via the bonding material 220 to create a die assembly 224 such that the openings 222 in the bonding material 220 align with the openings 216 in the carrier 200, and that the recessed edges 218 of the die 202 align with the recessed edges 214 of the carrier 200 resulting in the configuration in FIG. 2F.

A mounting side 226 of the die 202 opposite that of the active layer 204 is backgrinded 266 to create a substantially even edge 228 on each side of the die 202 resulting in the configuration in FIG. 2G. A third photoresist material layer 230 overlies the mounting side 226 of the die 202 and is patterned and developed to create openings 232 to thereby expose a portion or portions of the mounting side 226 of the die 202 resulting in the configuration in FIG. 2H. The third photoresist material layer 230 can have a thickness that varies in correspondence with the wavelength of radiation used to pattern the third photoresist material layer 230. The third photoresist material layer 230 may be formed via spin-coating, spin casting deposition techniques, laser printing, or film type photoresist lamination selectively irradiated (e.g., via deep ultraviolet (DUV) irradiation).

The configuration in FIG. 2H undergoes a second etching process 268 to create trenches 234 in the die 202 and the third photoresist material layer 230 is subsequently removed resulting in the configuration in FIG. 2I. The trenches 234 extend into the die 202 from the mounting side 226 of the die 202 to the active layer 204. A material 236 comprised of either a dielectric material (e.g., polyimide, SiO₂) or a conductive material (e.g., copper) is deposited in the trenches 234 and on the mounting side 226 of the die 202 via a spin-on process 270 resulting in the configuration in FIG. 2J. Referring to FIG. 2K, the configuration in FIG. 2J is rotated 180°. A backside of the carrier 200 is backgrinded 272 in the configuration in FIG. 2K to remove the recessed edges 214, and to expose portions of the active layer 204 via the aligned openings 216, 222 (combined openings 238) in the carrier 200 and the bonding material 220 respectively resulting in the configured die assembly 224 in FIG. 2L.

The mounting side 226 of the die is attached to a die pad 240 of a leadframe 242 via a die attach material 244 to thereby attach the die assembly 224 to the leadframe 242 resulting in the configuration in FIG. 2M. Conductive wire bonds (e.g., gold, palladium coated copper (PCC), copper, aluminum) 246 are connected from the active layer 204 by wire bonding (e.g., ball bonding) 248 to leads 250 of the leadframe 242. Specifically, the wire bonds 246 are connected to the exposed portions of the active layer 204 of the die 202 where the combined openings 238 are formed resulting in the configuration in FIG. 2N. A molding compound 252 is formed over the carrier 200, the die 202 including the active layer 204, and the wire bonds 246 resulting in the configured electronic device 254 in FIG. 2O. In addition, the molding compound 252 covers all but one surface of the leadframe 242, where the one surface not covered faces away from the die 202 and the electronic device 254.

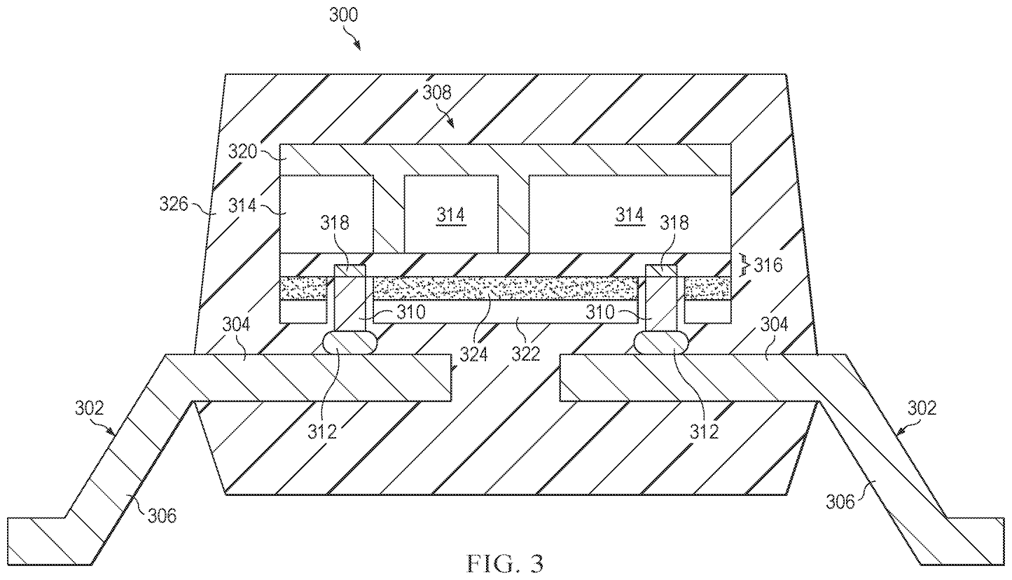

FIG. 3 is a cross-sectional view of another example electronic device (e.g., integrated circuit (IC) package) 300 that includes a reinforcement layer. The electronic device 300 can be comprised of non-leaded IC packages described above or leaded IC packages described below. Some example IC packages can include a quad flat no-lead (QFN) package, a quad flat package (QFP), a small outline package (SOP), a single in-line package (SIP), a double in-line package (DIP), etc.

The electronic device 300 includes a leadframe 302 comprising inner leads 304 and outer leads 306. A die assembly 308 is attached to the inner leads 304 of the leadframe 302 via conductive pillars (e.g., copper) 310 and an adhesive (e.g., solder) 312. The die assembly 308 includes a die 314 having an active layer 316. The active layer 316 is similar to the active layer 114 described above and illustrated in FIG. 1B and thus the description of the active layer 316 will not be repeated. The active layer 316 includes conductive pads (e.g., aluminum, copper) 318 for bonding the conductive pillars 310 to the die 314. One or more trenches are defined in the die 314 and extend from the active layer 316 of the die 314 to an opposite side of the die 314. The trenches are filled with either a material 320 comprising either an isolating/barrier material (e.g., polyimide, SiO₂) for use in isolation packages or with a conductive material (e.g., copper) for use in sensor packages.

The die assembly 308 further includes a reinforcement layer (cap) 322 attached to the active layer 316 of the die via a bonding material 324. The reinforcement layer 322 provides additional stiffness to the active layer 316 and the die 314 to reduce the potential for cracks as explained above. The reinforcement layer 322 is comprised of the original wafer carrier (e.g., silicon carrier, glass carrier, ceramic carrier) that is attached to the die 314 during fabrication of the electronic device 300. Openings are formed in the reinforcement layer 322 where the conductive pillars 310 are formed. The conductive pillars 310 provide a connection from the active layer 316 of the die 314 to the inner leads 304 of the leadframe 302. A mold compound 326 is formed over and encapsulates the die assembly 308 including the die 314, the reinforcement layer 322, and the conductive pillars 310. In addition, the mold compound 326 encapsulates the inner leads 304 but not the outer leads 306.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe having a die pad and leads;
a die attached to the die pad, the die including an active layer;
a reinforcement layer disposed on the active layer;
wire bonds attached from the active layer of the die to the leads; and
a mold compound encapsulating the die, the reinforcement layer, and the wire bonds.

2. The electronic device of claim 1, wherein the reinforcement layer is comprised of a wafer carrier used to carry the die during a fabrication process.

3. The electronic device of claim 2, wherein the wafer carrier is comprised of at least one of a silicon wafer carrier, a glass wafer carrier, and a ceramic wafer carrier.

4. The electronic device of claim 1, wherein the die further includes at least one trench defined therein, the trench extending from a mounting side of the die to the active layer.

5. The electronic device of claim 4, wherein the active layer includes an insulation material, at least one metal layer embedded in the insulation material, a conductive pad, and at least one via that connects the at least one metal layer to the conductive pad, the at least one metal layer being disposed over the at least one trench.

6. The electronic device of claim 4, wherein the at least one trench is filled with a dielectric material.

7. The electronic device of claim 4, wherein the at least one trench is filled with an electrically conductive material.

8. The electronic device of claim 1, wherein the reinforcement layer includes openings defined therein to facilitate an attachment of the wire bonds to the active layer.

9. The electronic device of claim 1, wherein the mold compound covers all but one surface of the leadframe, the one surface facing away from the electronic device.

10. The electronic device of claim 1, wherein the die is attached to the die pad via a die attach material.

11. A method comprising:
providing a carrier and a die, the die having an active layer;
performing a first etching process to the carrier and the die;
bonding the die to the carrier to create a die assembly;
backgrinding a mounting side of the die;
performing a second etching process on the die to create at least one trench in the die;
depositing at least one of a dielectric material or an electrically conductive material in the at least one trench and on the mounting side of the die;
backgrinding the carrier;
placing the die assembly on a die pad of a leadframe;
attaching wire bonds from the active layer of the die to leads of the leadframe; and
forming a molding compound over the die, the carrier, the wire bonds, and all but one surface of the leadframe, the one surface facing away from the die.

12. The method of claim 11, wherein performing a first etching process includes performing a first etching process to the carrier to create recessed edges on each side of the carrier and to create openings in the carrier, and performing a first etching process to the die to create recessed edges on each side of the die.

13. The method of claim 12, wherein prior to bonding the die to the carrier to create a die assembly, the method further comprising depositing a bonding material on the active layer of the die, forming openings in the bonding material that align with the openings in the carrier, and rotating the die 180°.

14. The method of claim 11, wherein prior to backgrinding the carrier, the method further comprising rotating the die assembly 180°.

15. The method of claim 11, wherein prior to performing a first etching process on the carrier and the die, the method further comprising:
forming a first photoresist material layer on the carrier;
patterning the first photoresist material layer to create openings in the first photoresist material layer;
forming a second photoresist material layer on the active layer of the die; and
patterning the second photoresist material layer to create openings in the second photoresist material layer.

16. The method of claim 15, wherein prior to performing a second etching process on the die to create at least one trench in the die, the method further comprising forming a third photoresist material layer on the mounting side of the die and patterning the third photoresist material layer to create openings in the third photoresist material layer.

17. An electronic device comprising:
a leadframe having inner leads and outer leads;
a die attached to the inner leads of the leadframe via conductive pillars, the die including an active layer;
a reinforcement layer disposed on the active layer; and
a mold compound encapsulating the die, the reinforcement layer, and the conductive pillars.

18. The electronic device of claim 17, wherein the reinforcement layer is comprised of a wafer carrier used to carry the die during a fabrication process.

19. The electronic device of claim 17, wherein the die further includes at least one trench defined therein, the trench extending from a mounting side of the die to the active layer.

20. The electronic device of claim 19, wherein the active layer includes an insulation material, at least one metal layer embedded in the insulation material, conductive pads connected to the conductive pillars, and at least one via that connects the at least one metal layer to the conductive pads, the at least one metal layer being disposed over the at least one trench.
